(19) United States
(12) Patent Application Publication
(10) Pub. No.: US 2014/0291012 A1
(43) Pub. Date: Oct. 2, 2014

(54) Electronic Device

(71) Applicant: Tyco Electronics AMP GmbH, Bensheim (DE)

(72) Inventors: Alex Bormuth, Heppenheim (DE); Joachim Zapf, Limburgerhof (DE)

(73) Assignee: TYCO ELECTRONICS AMP GMBH, Bensheim (DE)

(21) Appl. No.: 14/245,513

(22) Filed: Apr. 4, 2014

Related U.S. Application Data
(63) Continuation of application No. PCT/EP2012/069055, filed on Sep. 27, 2012.

(30) Foreign Application Priority Data
Oct. 6, 2011 (DE) 102011084108.3

(51) Int. Cl. H05K 5/02; H05K 5/06; H05K 5/03

(52) U.S. Cl. CPC H05K 5/0247; H05K 5/03; H05K 5/06
USPC 174/521; 174/541; 29/428; 29/832

(57) ABSTRACT

An electronic device is disclosed having a housing with a single opening, and an inner space accessible solely through the opening. A covering plate is positioned within the opening. An electrically conductive contact pin extends through the covering plate and into the inner space.

### CROSS-REFERENCE TO RELATED APPLICATIONS

This application is a continuation of PCT International Application No. EP2012/069055 filed Sep. 27, 2012, which claims priority under 35 U.S.C. §119 to DE 10 2011 084108.3, filed Oct. 6, 2011.

### FIELD OF THE INVENTION

The present invention relates to an electronic device according to patent claim 1 and a method for producing an electronic device according to patent claim 13.

### BACKGROUND

Electronic devices having housings are well known from the prior art. In many conventional electronic devices, the housing has an interface for a plug type connector. Furthermore, the housing generally has an opening, which can be closed by the use of a cover. During the production of the electronic device, electronic components are installed in the housing of the electronic device through the opening of the housing. Subsequently, the opening of the housing of the electronic device is closed with the cover. If the housing of the electronic device is intended to comply with sealing requirements, the connection between the housing and the cover must be additionally sealed.

However, the requirement for a separate cover for the housing of the electronic device and the required additional operating steps for closing the housing with the cover and for sealing the connection between the housing and cover increase the manufacturing costs and assembly steps. Another disadvantage of conventional electronic devices is that necessary modifications to the plug type connector interface of the electronic device may sometimes be difficult to implement. Another disadvantage is that during the closure of the housing with the cover, and during the sealing of the connection between the housing and cover, the risk of damaging electronic components positioned inside the housing increases.

### SUMMARY

An electronic device is disclosed having a housing with a single opening, and an inner space accessible solely through the opening. A covering plate is positioned within the opening. An electrically conductive contact pin extends through the covering plate and into the inner space.

### BRIEF DESCRIPTION OF THE DRAWINGS

The invention will now be described by way of example, with reference to the accompanying figures, of which:

FIG. 1 shows a perspective view of a housing of an electronic device;

FIG. 2 shows a perspective view of a covering plate which is provided with contact pins and which is connected to a circuit board;

FIG. 3 is a perspective side view of the covering plate and the circuit board;

FIG. 4 is perspective rear view of the covering plate and the circuit board;

FIG. 5 is a sectional view of an electronic device;

FIG. 6 is a plan view of the fully assembled electronic device;

FIG. 7 is a perspective view of a covering plate having contact pins according to a second embodiment;

FIG. 8 a perspective view of the covering plate of the second embodiment connected to a circuit board; and

FIG. 9 is another perspective view of the circuit board and the covering plate according to the second embodiment.

### DETAILED DESCRIPTION OF THE EMBODIMENT(S)

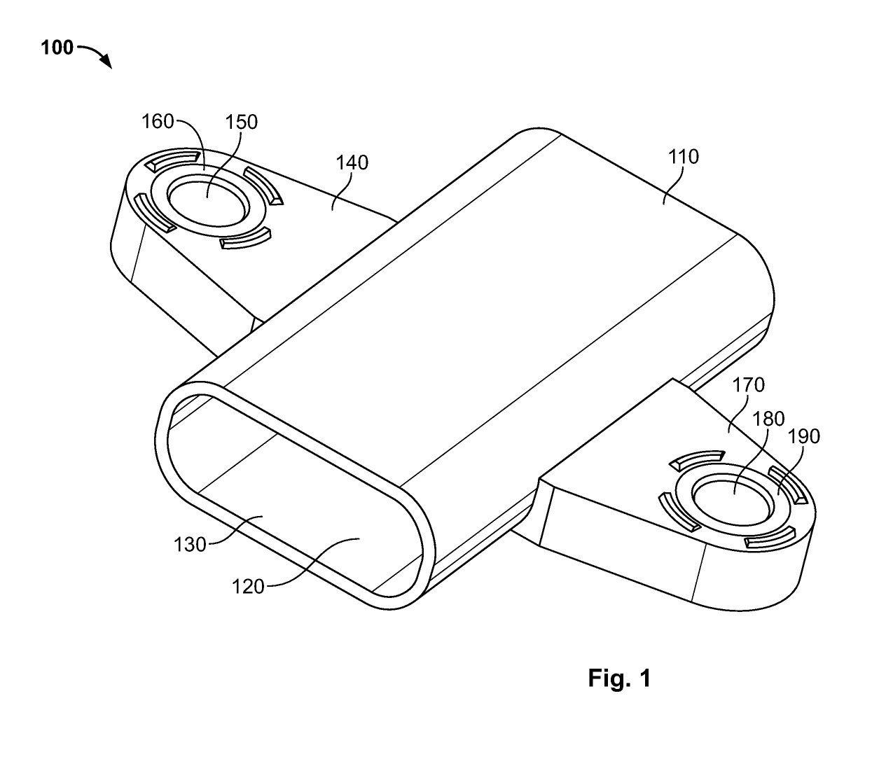

FIG. 1 shows an electronic device having a housing 100 with an electrically insulating material. The housing 100 may be made from a plastics material, and may be produced, by injection moulding.

The housing 100 includes a housing body 110 constructed in a hollow-cylindrical manner with an inner space 120. An opening 130 in one of the covering faces of the cylindrical housing body 110 forms a through-hole which permits the inner space 120 to be accessible from the outside. Apart from the opening 130, the housing body 110 has no other openings, but is instead completely closed. The inner space 120 of the housing body 110 is consequently accessible exclusively through the opening 130. The housing body 110 is constructed in an integral manner.

The housing 100 further has a first wing 140 and a second wing 170. The first wing 140 and the second wing 170 are positioned on an outer surface of the housing body 110, on opposing sides of the housing body 110, and extend away from each other in opposite directions. The first wing 140 has a first securing hole 150 which is constructed as a through-hole in the first wing 140. A first eyelet 160 is positioned in the first securing hole 150, and is made of a metal material. The first eyelet 160 is constructed as a short hollow-cylindrical sleeve and serves to mechanically strengthen the first securing hole 150. The second wing 170 has a second securing hole 180 which is constructed as a passage in the second wing 170. In the second securing hole 180, there is arranged a second eyelet 190 which is constructed in a similar manner to the first eyelet 160.

When the housing 100 is produced, the eyelets 160, 190 can either be injection-moulded with the material of the housing 100 or be pressed into the wings 140, 170 after the injection-moulding of the housing 100. In other exemplary embodiments, number of wings 140, 170, securing holes 150, 180, and eyelets 160, 190 can vary. For example, in one exemplary embodiment, only one wing 140 or 170 is used, and consequently, only one securing hole 150 or 180, and one eyelet 160 or 190 will also be used. Further, in other exemplary embodiments, the eyelet 160 or 190 is not used.

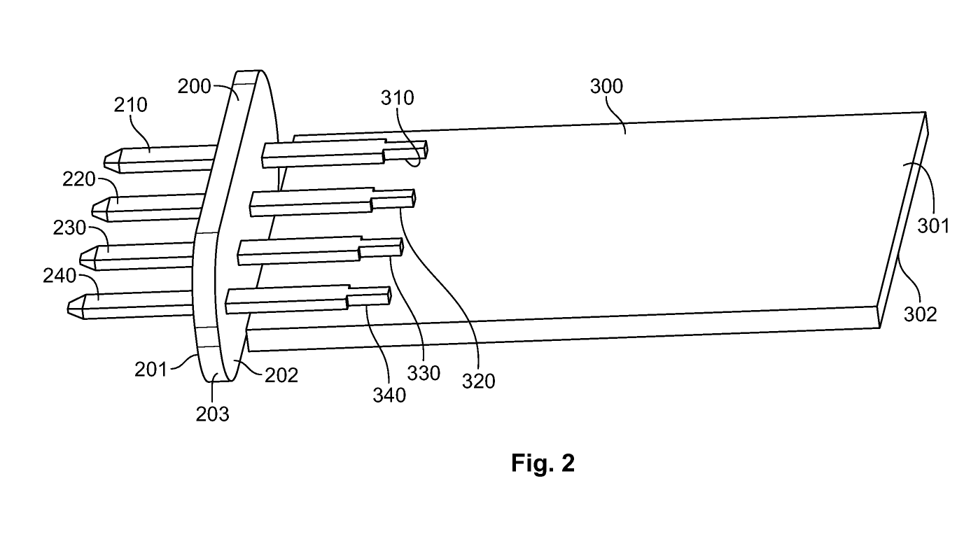

FIG. 2 illustrates an exemplary embodiment of the covering plate 200 having a small flat plate with a first surface, which forms an outer side 201, and a second surface opposite the first surface, which forms an inner side 202. Between the inner side 202 and the outer side 201, a peripheral edge 203 of the covering plate 200 is formed. The shape and the dimensions of the covering plate 200 correspond to the shape and the dimensions of the opening 130 of the housing 100. The covering plate 200 can thus be inserted into the opening 130 of the housing 100 such that the opening 130 is closed by the covering plate 200. The covering plate may be made from an electrically insulating material, such as the plastics material used to make the housing 100.

A first contact pin 210, a second contact pin 220, a third contact pin 230 and a fourth contact pin 240 extend through the covering plate 200, orthogonal to the first surface of the outer side 201. In other exemplary embodiments, more or less than four contact pins 210, 220, 230, 240 may also be provided. The contact pins 210, 220, 230, 240 are made from an electrically conductive material, such as commonly used conductive metals known to those of ordinary skill in the art. The contact pins 210, 220, 230, 240 are constructed as elongated rods or bars. Each of the contact pins 210, 220, 230, 240 extends from the first surface of outer side 201 of the covering plate 200, through the covering plate 200 to the inner side 202 of the covering plate 200. The regions of the contact pins 210, 220, 230, 240 in contact with the cover plate 200 as they pass through the covering plate 200, are constructed in an air-tight and water-tight manner.

FIG. 2 further shows an exemplary embodiment having a circuit board 300. The circuit board 300 may also be referred to as a board or a PCB (printed circuit board). In one exemplary embodiment, the circuit board 300 is a printed circuit board. There may be arranged on the circuit board 300 electrical strip conductors and electronic components which are not illustrated in FIG. 2. The circuit board 300 has an upper side 301 and an opposing lower side 302 which is on an opposite face of the circuit board 300 than the upper side 301. Strip conductors and electronic components may be provided on the upper side 301, on the lower side 302 or both on the upper side 301 and on the lower side 302 of the circuit board 300. (not shown)

The covering plate 200 is connected to the circuit board 300 in such a manner that portions of the contact pins 210, 220, 230, 240 extending orthogonal from the inner side 202 of the covering plate 200 rest flat on the upper side 301 of the circuit board 300. Between the first contact pin 210 and the upper side 301 of the circuit board 300, a first solder connection 310 is positioned. Between the second contact pin 220 and the upper side 301 of the circuit board 300 a second solder connection 320 is positioned. Between the third contact pin 230 and the upper side 301 of the circuit board 300 a third solder connection 330 is positioned. Between the fourth contact pin 240 and the upper side 301 of the circuit board 300 a fourth solder connection 340 is positioned. The solder connections 310, 320, 330, 340 are in contact with the contact pins 210, 220, 230, 240, and produce electrically conductive connections between the contact pins 210, 220, 230, 240 and strip conductors and/or electronic components on the circuit board 300. The solder connections 310, 320, 330, 340 may have been produced, for example, by means of reflow soldering.

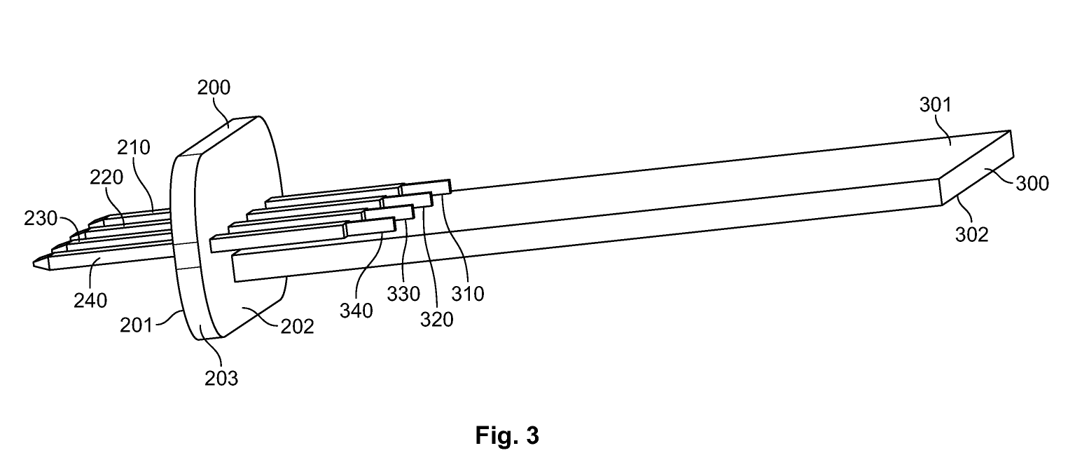

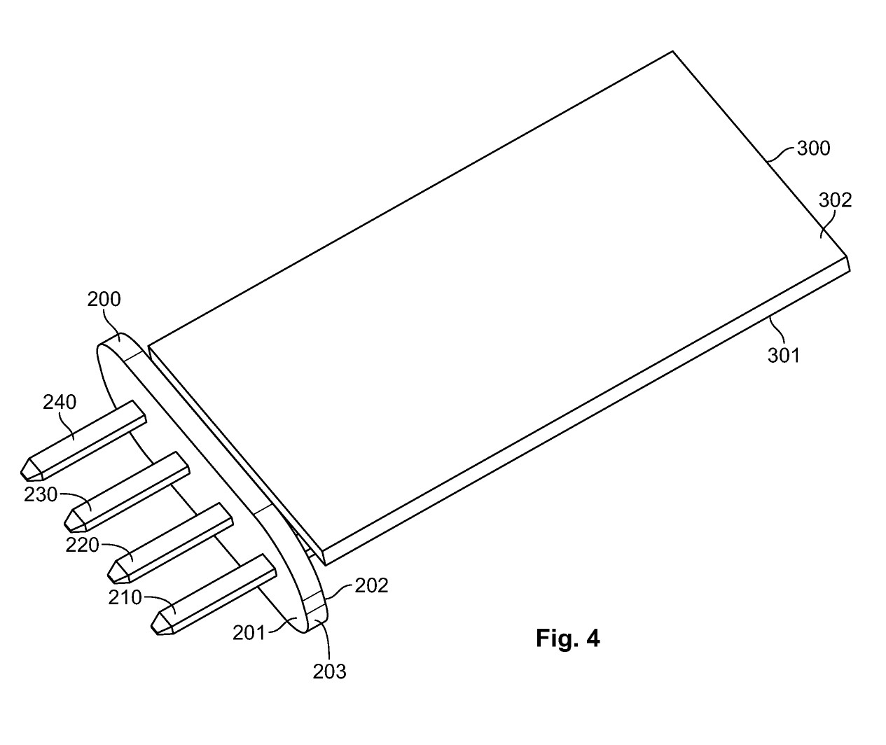

FIG. 3 is a side view of the covering plate 200 and the circuit board 300 which is connected to the covering plate 200 through the contact pins 210, 220, 230, 240. FIG. 4 is a rear view of the circuit board 300 and the covering plate 200 which is connected to the circuit board 300.

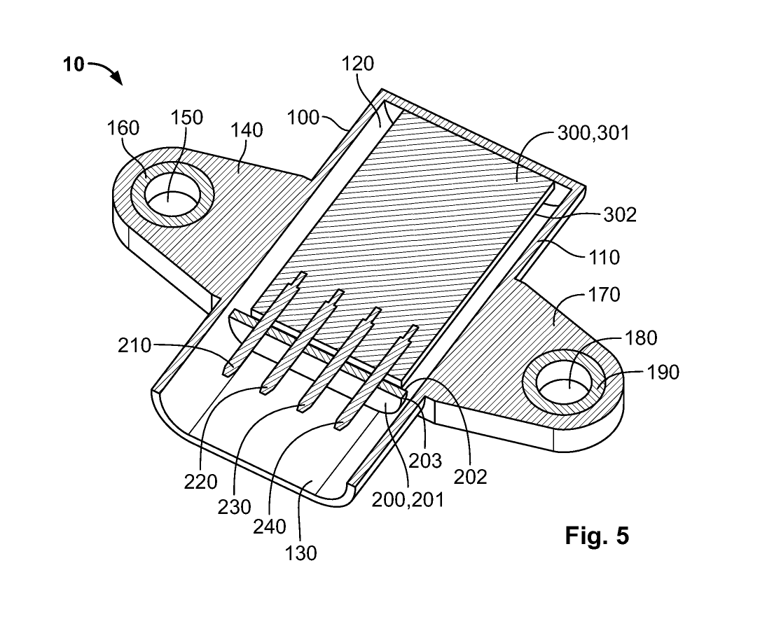

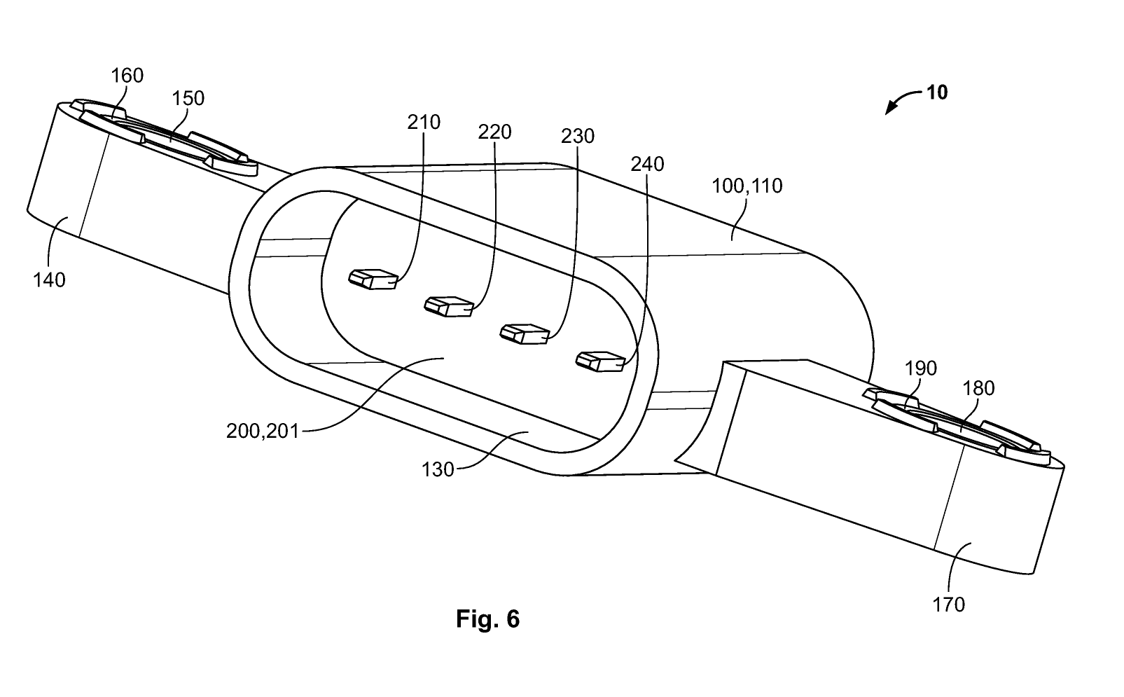

FIG. 5 is a sectioned illustration of a fully assembled electronic device 10. FIG. 6 is a perspective view of the fully assembled electronic device 10. The electronic device 10 comprises the housing 100, the circuit board 300 and the covering plate 200.

The covering plate 200 with the contact pins 210, 220, 230, 240 which extend through the covering plate 200 and the circuit board 300 which is connected to the covering plate 200 through the contact pins 210, 220, 230, 240, were inserted through the opening 130 into the inner space 120 of the housing body 110. Since the circuit board 300 was inserted together with the covering plate 200 through the opening 130 into the inner space 120 of the housing body 110, the housing 100 advantageously does not have to have any additional openings for assembling the circuit board 300. Therefore, no additional openings of the housing 100 also have to be closed, which reduces the number of manufacturing steps. Further, mechanical loads on the housing 100 and the circuit board 300, which are commonly asserted during the closure of such an additional opening, are advantageously prevented.

In an exemplary embodiment, on the covering plate 200 and/or in the region of the opening 130 of the housing body 110, a catch and latching mechanism may be used (not illustrated in FIG. 5) to engage the covering plate 200 in the opening 130.

A complimentary plug type connector (not illustrated) may be fitted to the opening 130 in order to contact the contact pins 210, 220, 230, 240 positioned on the covering plate 200. In this exemplary embodiment, the plug type connector surrounds the housing body 110 along an outer periphery of the opening 130, and acts as a seal for the opening 130 against the infiltration of dust, dirt and moisture.

In another exemplary embodiment, the covering plate 200 can seal the inner space 120 in the absence of a plug type connector, in the region between the edge 203 of the covering plate 200 and the wall of the housing body 110 a seal may additionally be provided. This seal may be an O-ring or a K seal.

One or more of the contact pins 210, 220, 230, 240 of the electronic device 10 may serve to teach, set, calibrate, initialize, or otherwise adjust, electronic components which are positioned in the inner space 120, particularly when the electronic components positioned on the circuit board 300 of the electronic device 10 comprise one or more sensors. One or more of the contact pins 210, 220, 230, 240 of the electronic device 10 may also serve to test functionality of an electronic component which is positioned in the inner space 120.

Advantageously, the teaching and testing can already be carried out before the installation of the circuit board 300 and the covering plate 200 into the inner space 120. The circuit board 300 can be connected to the covering plate 200 and the contact pins 210, 220, 230, 240 directly after the circuit board 300 has been produced and equipped. Subsequently, the electronic components which are arranged on the circuit board 300 can be tested and/or taught. If the tests and/or this teaching are carried out successfully, the circuit board 300 and the covering plate 200 can be inserted and positioned in the inner space 120. If the circuit board 300 or one of the electronic components positioned on the circuit board 300 is found to be defective, further assembly of the defective circuit board 300 can be prevented.

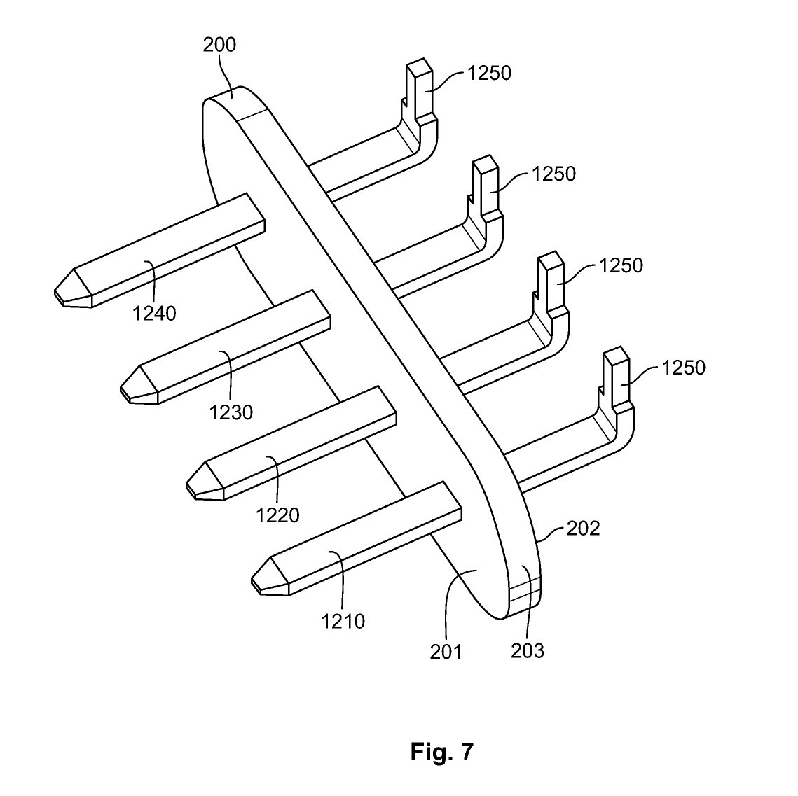

FIG. 7 is perspective view of a second embodiment of the covering plate 200. In FIG. 7, the second embodiment discloses a first contact pin 1210, a second contact pin 1220, a third contact pin 1230 and a fourth contact pin 1240 extend through the covering plate 200. As previously shown in the first embodiment illustrated in FIG. 2, more or less than four contact pins 1210, 1220, 1230,1240 may also be provided. Each of the contact pins 1210, 1220, 1230, 1240 extends from the first surface of outer side 201 of the covering plate 200, through the covering plate 200 to the inner side 202 of the covering plate 200. The regions of the contact pins 1210, 1220, 1230, 1240 in contact with the cover plate 200 as they pass through the covering plate 200, are constructed in an air-tight and water-tight manner.

The contact pins 1210, 1220, 1230, 1240 are the same as the contact pins 210, 220, 230, 240 of the first embodiment, but differ in that the contact pins 1210, 1220, 1230, 1240 each have an angled insertion portion 1250 in which the contact pins 1210, 1220, 1230, 1240 are bent at right angles. The angled insertion portions 1250 are positioned at the longitudinal end portions of the contact pins 1210, 1220, 1230, 1240 extending orthogonally from the inner side 202 of the covering plate 200. The contact pins 1210, 1220, 1230, 1240 are made from an electrically conductive material, such as commonly used conductive metals known to those of ordinary skill in the art.

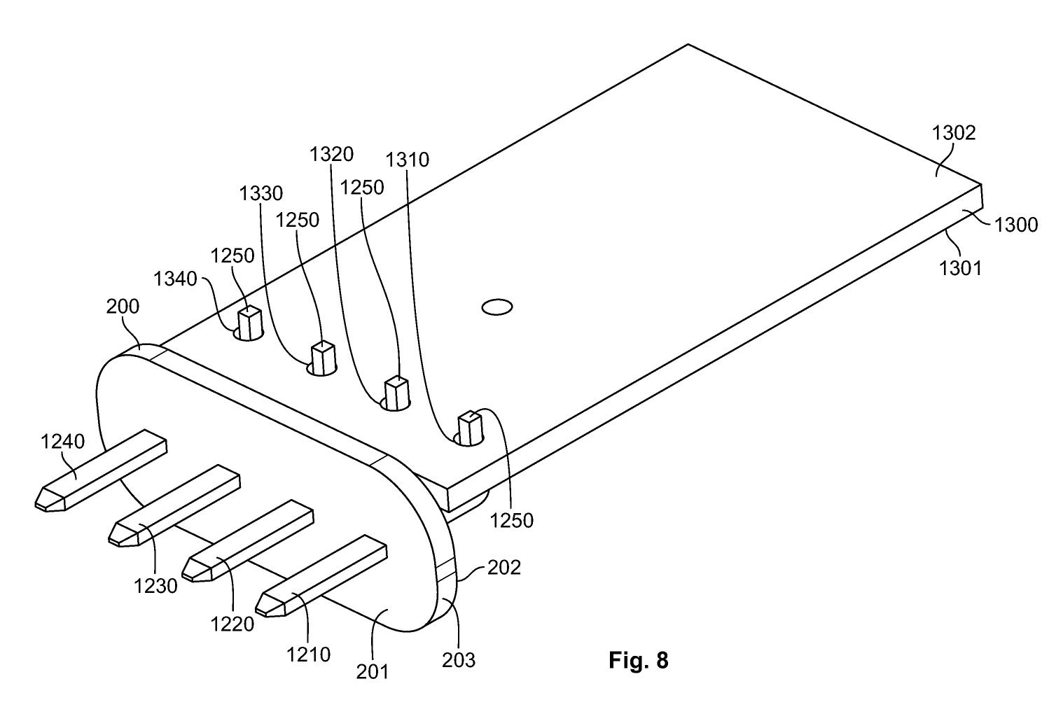

FIG. 8 illustrates of the covering plate 200 with the contact pins 1210, 1220, 1230, 1240 according to the second embodiment. Furthermore, FIG. 8 shows a circuit board 1300 according to the second embodiment. The circuit board 1300 may be a printed circuit board having an upper side 1301 and an opposing lower side 1302, which is on an opposite face of the circuit board 300 than the upper side 301. Strip conductors and electronic components may be provided on the upper side 1301. on the lower side 1302, or both on the upper side 1301 and on the lower side 1302 of the circuit board 1300.

The circuit board 1300 has a first contact opening 1310, a second contact opening 1320, a third contact opening 1330 and a fourth contact opening 1340. The angled insertion portion 1250 of the first contact pin 1210 is inserted from the upper side 1301 through the first contact opening 1310. The angled insertion portion 1250 of the second contact pin 1220 is inserted from the upper side 1301 through the second contact opening 1320. The angled insertion portion 1250 of the third contact pin 1230 is inserted from the upper side 1301 through the third contact opening 1330 of the circuit board 1300. The angled insertion portion 1250 of the fourth contact pin 1240 is inserted from the upper side 1301 through the fourth contact opening 1340.

In the first contact opening 1310, there is an electrically conductive connection between the first contact pin 1210 and a strip conductor positioned on the circuit board 1300, or an electronic component positioned on the circuit board 1300. In the second contact opening 1320 there is an electrically conductive connection between the second contact pin 1220 and a conductive component on the circuit board 1300. In the third contact opening 1330, there is an electrically conductive connection between the third contact pin 1230 and an electrically conductive component on the circuit board 1300. In the fourth contact opening 1340, there is an electrically conductive connection between the fourth contact pin 1240 and an electrically conductive component on the circuit board 1300.

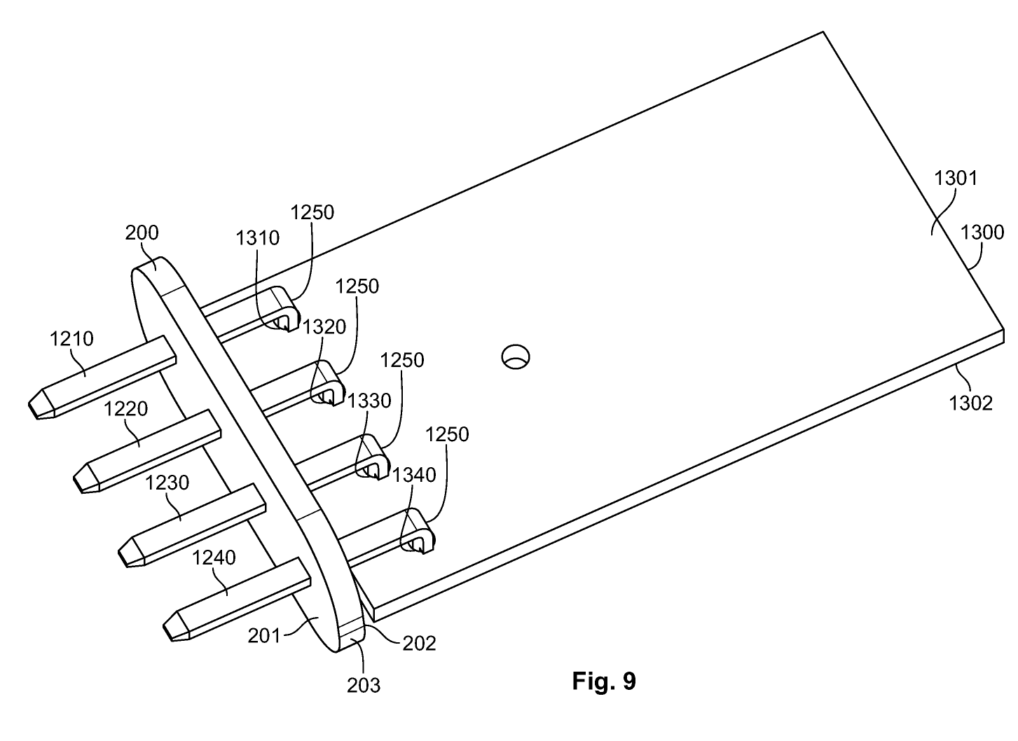

FIG. 9 is a rear view of the circuit board 1300 and the covering plate 200 with the contact pins 1210, 1220, 1230, 1240 according to the second embodiment.

The second embodiment of the circuit board 1300 illustrated with reference to FIGS. 7 to 9 and the contact pins 1210, 1220, 1230, 1240 is particularly suitable when reflow soldering for electrically connecting the contact pins 1210, 1220, 1230, 1240 to the circuit board 1300 is not possible or is not desirable. The contact pins 1210, 1220, 1230, 1240 may be soldered in the contact openings 1310, 1320, 1330, 1340.

The combination of the circuit board 1300 with the covering plate 200 illustrated in FIGS. 8 and 9 can subsequently be calibrated, tested or taught via the contact pins 1210, 1220, 1230, 1240 by the method disclosed above for the first embodiment. The circuit board 1300 and the covering plate 200 secured to the circuit board 1300 are again inserted through the opening 130 into the inner space 120 of the housing body 110 of the housing 100 in order to produce a complete electronic device 10.

Advantageously, in this electronic device 10, no separate cover is required for closing an opening of the housing of the electronic device. Advantageously, operating steps for closing additional openings of the housing of the electronic device 10 can thereby be dispensed with during the production of the electronic device 10. Another advantage of the electronic device 10 is that additional contact pins can be arranged in the covering plate without great complexity.

What is claimed is:

1. An electronic device comprising:
a housing having
a single opening, and
an inner space accessible solely through the opening;
a covering plate positioned within the opening; and
an electrically conductive contact pin extending through the covering plate and into the inner space.

2. The electronic device of claim 1, further comprising a circuit board positioned in the inner space.

3. The electronic device of claim 2, wherein the contact pin is inserted into a contact opening of the circuit board.

4. The electronic device of claim 3, wherein the contact pin is solderable to the circuit board.

5. The electronic device of claim 4, wherein the contact pin is solderable to the circuit board by reflow soldering.

6. The electronic device of claim 1, further comprising an electronic component positioned in the inner space.

7. The electronic device of claim 1, wherein when a complementary plug type connector is received in the opening, the connector contacts the contact pin and seals the housing.

8. The electronic device of claim 1, further comprising a catch and latch mechanism positioned on the covering plate and the housing.

9. The electronic device of claim 1, further comprising a seal positioned between the covering plate and the housing.

10. The electronic device according to claim 1, wherein the housing is comprised of a plastic material.

11. The electronic device claim 1, wherein the housing further comprises a wing having a securing hole.

12. The electronic device of claim 11, further comprising a metal eyelet positioned in the securing hole.

13. A method for producing an electronic device comprising the following steps:
providing a housing having a single opening and an inner space accessible solely through the opening;
providing a covering plate having a contact pin extending through the covering plate; and
inserting the covering plate into the opening.

14. The method of claim 13, wherein the contact pin is connected to a circuit board before the covering plate is inserted into the opening.

15. The method of claim 14, wherein an electronic component is positioned on the circuit board and calibrated before the covering plate is inserted into the opening.

16. The method of claim 13, wherein the circuit board is positioned in the inner space when the covering plate is inserted into the opening.

17. The method of claim 13, wherein the inner space is sealed when the covering plate is inserted into the opening.

18. The method of claim 13, further comprising the step of providing a seal between the covering plate and the housing.
